(19) United States
(12) Patent Application Publication
(10) Pub. No.: US 2017/0330855 A1
(43) Pub. Date: Nov. 16, 2017

(54) System and Method for Immersion Bonding

(71) Applicant: Taiwan Semiconductor Manufacturing Company, Ltd., Hsin-Chu (TW)

(72) Inventors: Chih-Hang Tung, Hsin-Chu (TW); Su-Chun Yang, Hsin-Chu (TW); Tung-Liang Shao, Hsin-Chu (TW); Chen-Hua Yu, Hsin-Chu (TW)

(21) Appl. No.: 15/154,338

(22) Filed: May 13, 2016

(51) Int. Cl. H01L 23/00; H01L 25/065; H01L 25/00

(52) U.S. Cl. CPC H01L 24/83; H01L 25/50; H01L 25/0657; H01L 2224/83359; H01L 2224/83054; H01L 2224/29078; H01L 2224/94; H01L 2225/06513; H01L 2224/83085

(57) ABSTRACT

A representative system and method for manufacturing stacked semiconductor devices includes disposing an aqueous alkaline solution between a first semiconductor device and a second semiconductor device prior to bonding. In a representative implementation, first and second semiconductor devices may be hybrid bonded to one another, where dielectric features of the first semiconductor device are bonded to dielectric features of the second semiconductor device, and metal features of the first semiconductor device are bonded to metal features of the second semiconductor device. Immersion bonds so formed demonstrate a substantially lower incidence of delamination associated with bond defects.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-20 nm node), which allows more components to be integrated into a given area. As the demand for miniaturization, higher speed and greater bandwidth, as well as lower power consumption and latency has grown recently, there has developed a need for smaller and more creative packaging techniques of semiconductor dies.

As semiconductor technologies further advance, stacked semiconductor devices, e.g., 3D integrated circuits (3DIC), have emerged as an effective alternative to further reduce the physical size of a semiconductor device. In a stacked semiconductor device, active circuits such as logic, memory, processor circuits and the like are fabricated on different semiconductor wafers. Two or more semiconductor wafers may be mated to one another to further reduce the form factor of the semiconductor device.

Two semiconductor wafers or dies may be bonded together through suitable bonding techniques. Commonly used bonding techniques include direct bonding, chemically activated bonding, plasma activated bonding, anodic bonding, eutectic bonding, glass frit bonding, adhesive bonding, thermo-compressive bonding, reactive bonding, and/or the like. An electrical connection may be provided between the stacked semiconductor wafers. The stacked semiconductor structures provide higher device densities with smaller form factors, and allow for increased performance with lower power consumption.

### BRIEF DESCRIPTION OF THE DRAWINGS

Aspects of the present disclosure are best understood from the following detailed description when read with the accompanying figures. It is noted that, in accordance with standard practice in the industry, various features are not drawn to scale. In fact, the dimensions of the various features may be arbitrarily increased or reduced for clarity of discussion.

FIG. 1 representatively illustrates a region of a first semiconductor wafer (or device) bonded to a region of a second semiconductor wafer (or device), in accordance with an embodiment.

FIG. 2 representatively illustrates a first semiconductor device hybrid bonded to a second semiconductor device, in accordance with an embodiment.

FIGS. 3A, 3B, and 3C representatively illustrate immersion bonding of first and second semiconductor devices, in accordance with various embodiments.

FIGS. 3A′, 3B′, 3C′, 3D, and 3D′ representatively illustrate bonding of first and second semiconductor devices with aqueous solution disposed therebetween, in accordance with various embodiments.

FIGS. 4 and 5 illustrate bonding of first and second semiconductor devices at various stages of manufacture, in accordance with an embodiment.

FIG. 6 representatively illustrates an apparatus for vapor phase immersion bonding of first and second semiconductor devices, in accordance with an embodiment.

FIG. 7 representatively illustrates a method for x-ray photoelectron spectroscopy (XPS) analysis of a semiconductor device surface adapted for immersion bonding, in accordance with an embodiment.

FIG. 8 representatively illustrates XPS data obtained from a semiconductor device surface adapted for immersion bonding, in accordance with an embodiment.

FIG. 9A representatively illustrates confocal scanning acoustic microscopy (CSAM) analysis of a bond formed in ambient atmosphere between a first semiconductor device and a second semiconductor device.

FIG. 9B representatively illustrates tunnelling electron microscopy (TEM) analysis of a cross-section of a bond formed in ambient atmosphere between a first semiconductor device and a second semiconductor device.

FIG. 10A representatively illustrates CSAM analysis of an immersion bond formed between a first semiconductor device and a second semiconductor device, in accordance with an embodiment.

FIG. 10B representatively illustrates TEM analysis of a cross-section of an immersion bond formed between a first semiconductor device and a second semiconductor device, in accordance with an embodiment.

FIG. 11 representatively illustrates an enlarged view of the TEM analysis of FIG. 10B.

FIG. 12 represenatively illustrates TEM analysis of a bridging layer cross-section of an immersion bond formed between a first semiconductor device and a second semiconductor device, in accordance with an embodiment.

FIGS. 13A, 14A, 15A, 16A, and 17A representatively illustrate perspective views of various manufacturing stages engaged after forming an immersion bond between a first semiconductor device and a second semiconductor device, in accordance with various embodiments.

FIGS. 13B, 14B, 15B, 16B, and 17B representatively illustrate elevation cross-sections of FIGS. 13A, 14A, 15A, 16A, and 17A, respectively.

FIGS. 18, 19A, and 19B representatively illustrate methods for manufacturing an immersion bonded semiconductor device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity, and does not in itself dictate a relationship between the various embodiments and/or configurations discussed.

Further, spatially relative terms, such as “beneath,” “below,” “lower,” “above,” “upper,” and the like, may be used herein for ease of description to describe one element's or feature's relationship to other elements or features, as illustrated in the figures. Spatially relative terms are intended to encompass different orientations of the device in use or operation in addition to the orientation depicted in the figures. The apparatus may be otherwise oriented (e.g., rotated 90 degrees or at other orientations) and the spatially relative descriptors used herein may likewise be interpreted accordingly.

A stacked semiconductor device package formed with hybrid bonding, and related methods of manufacture, are provided in accordance with various representative embodiments. Representative intermediate stages in the fabrication of an immersion bonded device package are illustrated. Throughout the various views and representative embodiments, like reference numbers are used to designate like elements.

In wafer-to-wafer bonding technology, several methods have been developed to bond package components together. Representative bonding methods include fusion bonding, eutectic bonding, direct metal bonding, hybrid bonding, and the like. In fusion bonding, an oxide surface of a wafer is bonded to an oxide surface (or a silicon surface) of another wafer. In eutectic bonding, two eutectic materials are placed in contact and are bonded with the application of pressure and heat. In typical applications, the eutectic materials are melted. When the melted eutectic materials cool and solidify, the wafers are bonded together. In direct metal-to-metal bonding, metal pads are pressed against one another at an elevated temperature with inter-diffusion bonding the metal pads to one another. In hybrid bonding, metal pads of two wafers are bonded to one another through direct metal-to-metal bonding, and an oxide surface of one of the wafers is bonded to an oxide surface (or a silicon surface) of the mated wafer.

With fusion bonding, additional electrical connections are typically provided to interconnect the bonded wafers. Registration accuracy of eutectic bonding may not meet certain device specifications, and there may be “metal-squeeze” resulting from melting of bonding metals. Throughput of direct metal-to-metal bonding is relatively low. With hybrid bonding, the metal pads typically have higher coefficients of thermal expansion (CTEs) than bond surface dielectric layers. This can result in delamination of the metal pads if the expansion volume of the metal pads is less than the dishing volume of the metal pads. Conversely, if the expansion volume of the metal pads is significantly greater than the dishing volume, the bonds between dielectric layers may delaminate. Delamination between bonded material layers in a finished semiconductor device package is generally undesirable.

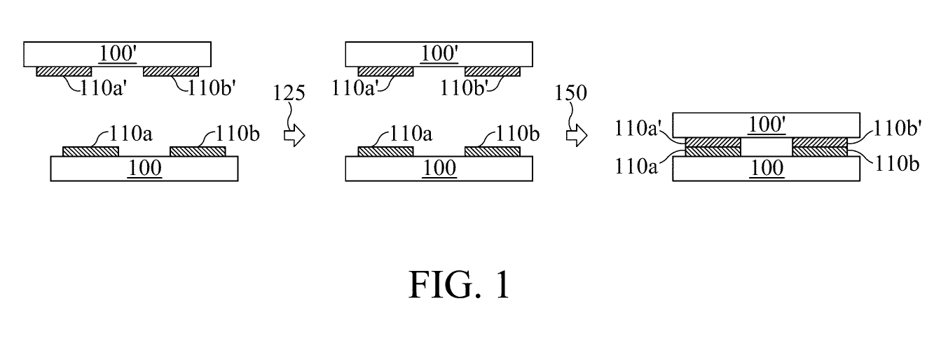

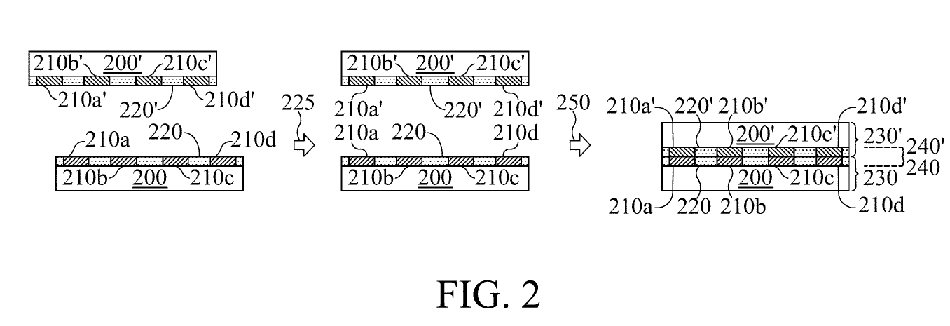

FIG. 1 representatively illustrates metal-to-metal bonding between a region of a first semiconductor device and a region of a second semiconductor device. First semiconductor device substrate 100 may be aligned 125 with and direct metal-to-metal bonded 150 to second semiconductor device substrate 100′ through first metal pads 110a, 110b of the first semiconductor device and second metal pads 110a′, 110b′ of the second semiconductor device. Alternatively, as representatively illustrated in FIG. 2, first semiconductor device substrate 200 may be aligned 225 with and hybrid bonded 250 to second semiconductor device substrate 200′ through metal-to-metal bonding between first semiconductor device metal pads 210a, 210b, 210c, 210d and second semiconductor device metal pads 210a′, 210b′, 210c′, 210d′, and dielectric-to-dielectric bonding between first semiconductor device dielectric material 220 and second semiconductor device dielectric material 220′.

First semiconductor device substrates 100, 200 and second semiconductor device substrates 100′, 200′ may comprise regions of corresponding device wafers, packaged wafers, interposer wafers, and/or the like or a combination thereof. In embodiments where semiconductor device substrates 100, 100′, 200, 200′comprise device wafers, semiconductor device substrates 100, 100′, 200, 200′ may correspond to regions of a semiconductor substrate, which may include, e.g., a silicon substrate. In other embodiments, semiconductor device substrates 100, 100′, 200, 200′ may be made of a suitable elemental semiconductor (e.g., such as diamond or germanium), a suitable compound semiconductor (e.g., such as gallium arsenide, silicon carbide, indium arsenide, or indium phosphide), a suitable alloy semiconductor (e.g., such as silicon germanium carbide, gallium arsenic phosphide, or gallium indium phosphide), or the like. Semiconductor device substrates 100, 100′, 200, 200′may further comprise other features such as various doped regions, a buried layer, and/or an epitaxy layer. Furthermore, semiconductor device substrates 100, 100′, 200, 200′ may be a semiconductor on insulator, such as silicon on insulator (SOI) or silicon on sapphire. In other embodiments, semiconductor device substrates 100, 100′, 200, 200′ may comprise a doped epitaxial layer or a gradient semiconductor layer, and/or may further include a semiconductor layer overlying another semiconductor layer of a different type, such as a silicon layer on a silicon germanium layer. In other examples, where semiconductor device substrates 100, 100′, 200, 200′ comprise a compound semiconductor, one or more of semiconductor device substrates 100, 100′, 200, 200′ may comprise a multilayer silicon structure, or semiconductor device substrates 100, 100′, 200, 200′ may include a multilayer compound semiconductor structure. Other substrates that may be used include gradient substrates, glass substrates, ceramic substrates, or hybrid orientation substrates.

Active devices (not shown) may be formed with connections on surfaces of semiconductor device substrates 100, 100′, 200, 200′, and may include, e.g., transistors, and/or the like. Metal lines (not shown) and vias (not shown) may be formed in dielectric layers (not shown), which may include inter-layer dielectric (ILD), inter-metal dielectric (IMD) layers, passivation layers, and/or the like. In some embodiments, ILD layers and IMD layers may comprise low-k dielectric layers which have dielectric constants (k values) smaller than a pre-determined value (e.g., less than about 3.5, less than about 3.0, less than about 2.9, less than about 2.5, etc.). Dielectric layers may include non-low-k dielectric materials having dielectric constants (k values) equal to or greater than 3.8. Metal traces (including metal lines and vias, not shown) may comprise aluminum, copper, nickel, tungsten, and/or the like, or alloys thereof. Metal lines and vias may be configured to interconnect active devices by, e.g., electrically coupling active devices to overlying metal features (not illustrated).

In some embodiments, a substrate may comprise an interposer wafer, which may be substantially free from active devices. Substrates may or may not include passive devices (not shown) such as resistors, capacitors, inductors, transformers, and/or the like, in accordance with some embodiments.

In representative embodiments, one or more substrates may comprise package substrates. In some embodiments, one or more substrates may comprise a laminate package substrate, wherein conductive traces (not shown) may be embedded in laminate dielectric layers (not shown). In other embodiments, one or more substrates may comprise built-up package substrates having cores (not shown) and conductive traces (not shown) built on opposite sides of the cores. The core of a built-up package substrate may include a fiber layer (not shown) and metallic features (not shown) substantially penetrating through the fiber layer, with the conductive traces interconnected through the metallic features. The conductive traces may be electrically coupled through conductive features in the cores.

In various embodiments where one or more substrates comprise a device wafer, an interposer wafer, a package substrate, or the like, dielectric layers may be formed, which may correspond to a top IMD layer. In some embodiments, one or more dielectric layers may comprise a low-k dielectric layer having k value less than about 3.0, less than about 2.9, less than about 2.5, or less than about 2.0. In other embodiments, one or more dielectric layers may comprise silicon oxide, silicon oxynitride, silicon nitride, and/or the like, or combinations thereof. Metal features may be formed in one or more dielectric layers, and may be electrically coupled to active devices (not shown) through metal lines and vias (not shown). Metal features may comprise metal lines or metal pads. Metal features may be formed of aluminum, copper, nickel, tungsten, and/or the like, or alloys thereof, or other suitable materials. Top surfaces of a dielectric layer and top surfaces of metal features may be substantially level with respect to one another, and/or within a same plane. In embodiments where one or more substrates comprises a device wafer, a dielectric layer and metal features may be on a front side (e.g., a side with active devices) or a backside (e.g., a side underlying the substrate) of the device wafer. For example, FIG. 2 representatively illustrates first semiconductor device substrate 200, front side layer 240 of first semiconductor device region of wafer 230 comprising first dielectric material 220 and first metal pads 210a, 210b, 210c, 210d, second semiconductor device substrate 200′, and front side layer 240′ of second semiconductor device region of wafer 230′ comprising second dielectric material 220′ and second metal pads 210a′, 210b′, 210c′, 210d′.

Metal lines and vias (not shown) or other metal features may include a copper-containing region (not shown) and a conductive barrier layer separating the copper-containing region from proximate dielectric material. The conductive barrier layer may include titanium, titanium nitride, tantalum, tantalum nitride, and/or the like, or combinations thereof.

In some embodiments, a plurality of device feature layers may be formed to include, e.g., an etch stop layer (not shown), a non-porous dielectric layer (not shown), a porous dielectric layer (not shown), and/or a dielectric barrier layer (not shown). Overlying ones of the plurality of device feature layers may be in physical contact with respective underlying layers. In some embodiments, an etch stop layer may comprise silicon carbide, silicon nitride, silicon oxynitride, and/or other dielectric materials, or combinations thereof. A non-porous dielectric layer may comprise a non-low-k dielectric layer having a k value equal to or greater than about 3.8. The porosity of a non-porous dielectric layer may be lower than about 5 percent. In some representative embodiments, a non-porous dielectric layer may be formed of un-doped silicate glass (USG), silicon oxide, and/or the like, and may be formed by a chemical vapor deposition (CVD) method, such as high-density plasma CVD (HDPCVD), plasma enhanced CVD (PECVD), atomic layer deposition (ALD), and/or the like.

A porous dielectric layer may comprise a low-k dielectric having a k value less than 3.8, less than about 3.0, or less than about 2.9. The k value of the dielectric layer may be between about 2.5 and 3.0. The porosity of the porous dielectric layer may be higher than the porosity of the non-porous dielectric layer. For example, the porosity of the porous dielectric layer may be higher than about 5 percent, or about 40 percent. The porosity of the porous dielectric layer may be selected to be lower than about 40 percent. In some representative embodiments, the porous dielectric layer comprises a carbon-containing dielectric. Materials for forming a non-porous dielectric layer may include SiO₂, phosphosilicate glass (PSG), fluorine-doped silicate glass (FSG), and/or the like. The dielectric barrier layer may comprise a dielectric material, e.g., a silicon-based dielectric, such as silicon nitride, silicon oxynitride, and/or the like. The dielectric barrier layer may be suitably configured to prevent, or otherwise substantially inhibit, diffusion of copper. Iterative application of various known photolithography, etching (e.g., isotropic or anisotropic), and fill processes may be used to pattern the layers to produce semiconductor device structures in first wafer 230 and second wafer 230′.

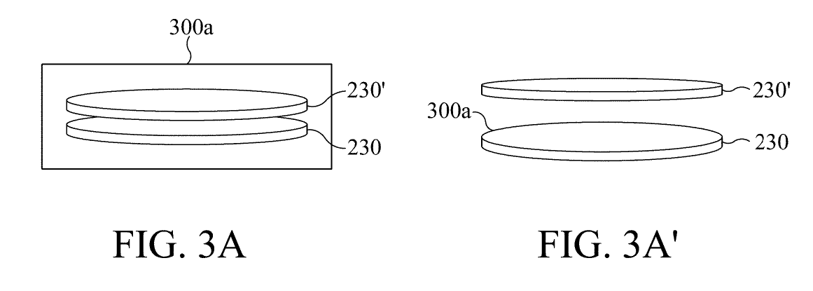

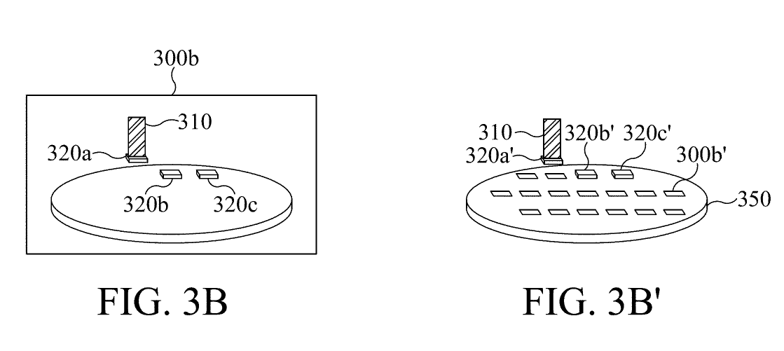

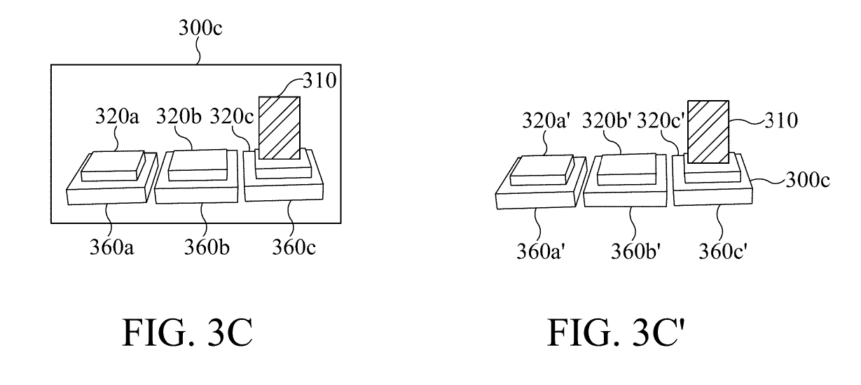

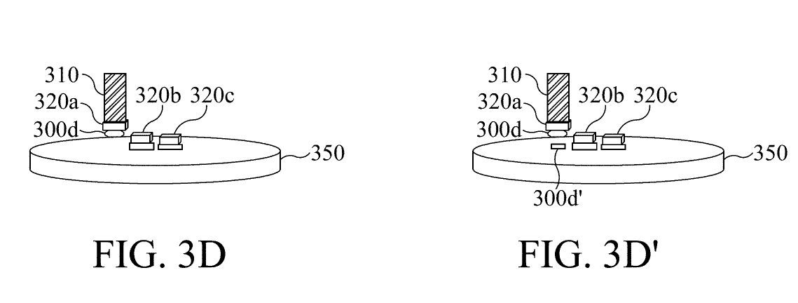

In a wafer-to-wafer embodiment, as representatively illustrated in FIG. 3A, first wafer 230 and second wafer 230′ may be aligned while substantially submerged in an aqueous solution 300a. As used herein, the term “aqueous solution” may correspond to a liquid phase or a vapor phase. In accordance with representative embodiments, an aqueous solution may comprise de-ionized water having a pH of about 7.0. Alternatively, an aqueous solution may comprise an alkaline solution having a pH of greater than about 7.0. In accordance with some embodiments, the alkaline solution may comprise hydroxide ion. In yet other representative embodiments, an aqueous solution may comprise a hydroxide-rich solution having a pH greater than about 9.0, or greater than about 11.0.

After submersion, first wafer 230 and second wafer 230′ may be bonded to one another. For example, front side layer 240 of first semiconductor wafer 230 maybe hybrid bonded to front side layer 240′ of second semiconductor wafer 230′, wherein metal pads 210a, 210b, 210c, 210d of first semiconductor wafer 230 are bonded to metal pads 210a′, 210b′, 210c′, 210d′ of second semiconductor wafer 230′, and dielectric material 220 of first semiconductor wafer 230 is bonded to dielectric material 220′ of second semiconductor wafer 230′, with the application of heat and pressure.

In an alternative wafer-to-wafer embodiment, as representatively illustrated in FIG. 3A′, first wafer 230 and second wafer 230′ may be aligned with aqueous solution 300a′ disposed on a front side surface of first wafer 230 and/or on a front side surface of second wafer 230′. Prior to bonding, aqueous solution 300a′ may be disposed between first wafer 230 and second wafer 230′.

After disposition of aqueous solution 300a′ between first wafer 230 and second wafer 230′, first wafer 230 and second wafer 230′ may be bonded to one another. For example, front side layer 240 of first semiconductor wafer 230 maybe hybrid bonded to front side layer 240′ of second semiconductor wafer 230′, wherein metal pads 210a, 210b, 210c, 210d of first semiconductor wafer 230 are bonded to metal pads 210a′, 210b′, 210c′, 210d′ of second semiconductor wafer 230′, and dielectric material 220 of first semiconductor wafer 230 is bonded to dielectric material 220′ of second semiconductor wafer 230′, with the application of heat and pressure.

In a chip-to-wafer embodiment, as representatively illustrated in FIG. 3B, semiconductor device dies 320a, 320b, 320c may be hybrid bonded to semiconductor wafer 350 while substantially submerged in aqueous solution 300b. A die pick-and-place tool 310 may be used to align and place semiconductor device die 320a on semiconductor wafer 350 while both are substantially submerged in aqueous solution 300b. After submersion, alignment, and landing, semiconductor device dies 320a, 320b, 320c and semiconductor wafer 350 may be bonded to one another. For example, semiconductor device dies 320a, 320b, 320c may be hybrid bonded to semiconductor wafer 350, wherein front side metal features of semiconductor device dies 320a, 320b, 320c are bonded to front side metal features of semiconductor wafer 350, and front side dielectric material of semiconductor device dies 320a, 320b, 320c are bonded to front side dielectric material of semiconductor wafer 350, with the application of heat and pressure.

In an alternative chip-to-wafer embodiment, as representatively illustrated in FIG. 3B′, semiconductor device dies 320a′, 320b′, 320c′ may be hybrid bonded to semiconductor wafer 350 with aqueous solution 300b′ disposed on a front side surface region of semiconductor wafer 350. Prior to bonding, aqueous solution 300b′ is disposed on semiconductor wafer 350 between semiconductor wafer 350 and semiconductor device dies 320a′, 320b′, 320c′.

A die pick-and-place tool 310 may be used to align and land semiconductor device die 320a′ over semiconductor wafer 350 with aqueous solution 300b′ disposed therebetween. After alignment and placement, semiconductor device dies 320a′, 320b′, 320c′ and semiconductor wafer 350 may be bonded to one another. For example, semiconductor device dies 320a′, 320b′, 320c′ maybe hybrid bonded to semiconductor wafer 350, wherein front side metal features of semiconductor device dies 320a′, 320b′, 320c′ are bonded to front side metal features of semiconductor wafer 350, and front side dielectric material of semiconductor device dies 320a′, 320b′, 320c′ are bonded to front side dielectric material of semiconductor wafer 350, with the application of heat and pressure.

In a chip-to-chip embodiment, as representatively illustrated in FIG. 3C, semiconductor device dies 320a, 320b, 320c may be hybrid bonded to semiconductor device dies 360a, 360b, 360c (respectively) while substantially submerged in aqueous solution 300c. Die pick-and-place tool 310 may be used to align and land semiconductor device die 320c over semiconductor device die 360c while both are substantially submerged in aqueous solution 300c. After submersion, alignment, and placement, semiconductor device dies 320a, 320b, 320c and semiconductor device dies 360a, 360b, 360c may be bonded to one another. For example, semiconductor device dies 320a, 320b, 320c maybe hybrid bonded to semiconductor device dies 360a, 360b, 360c (respectively), wherein front side metal features of semiconductor device dies 320a, 320b, 320c are bonded to front side metal features of semiconductor device dies 360a, 360b, 360c, and front side dielectric material of semiconductor device dies 320a, 320b, 320c are bonded to front side dielectric material of semiconductor device dies 360a, 360b, 360c, with the application of heat and pressure.

In an alternative chip-to-chip embodiment, as representatively illustrated in FIG. 3C′, first semiconductor device dies 320a′, 320b′, 320c′ may be hybrid bonded to second semiconductor device dies 360a′, 360b′, 360c′ (respectively) with aqueous solution 300c′ disposed between respective first and second semiconductor device dies. Die pick-and-place tool 310 may be used to align and land semiconductor device die 320c′ over semiconductor device die 360c′ with aqueous solution 300c′ disposed therebetween. After alignment and placement, semiconductor device dies 320a′, 320b′, 320c′ and semiconductor device dies 360a′, 360b′, 360′c may be respectively bonded to one another. For example, semiconductor device dies 320a′, 320b′, 320c′ maybe hybrid bonded to semiconductor device dies 360a′, 360b′, 360c′ (respectively), wherein front side metal features of semiconductor device dies 320a′, 320b′, 320c′ are bonded to front side metal features of semiconductor device dies 360a′, 360b′, 360c′, and front side dielectric material of semiconductor device dies 320a′, 320b′, 320c′ is bonded to front side dielectric material of semiconductor device dies 360a′, 360b′, 360c′, with the application of heat and pressure.

In another chip-to-wafer embodiment, as representatively illustrated in FIG. 3D, semiconductor device dies 320a, 320b, 320c may be hybrid bonded to semiconductor wafer 350 with aqueous solution 300d disposed on a front side surface region of semiconductor device dies 320a, 320b, 320c prior to hybrid bonding. Aqueous solution 300d may be disposed on semiconductor device dies 320a, 320b, 320c by operation of die pick-and-place tool 310 dipping semiconductor device dies 320a, 320b, 320c in a dip tank. Thereafter, die pick-and-place tool 310 aligns and lands semiconductor device dies (e.g., 320a) over semiconductor wafer 350 with aqueous solution 300d disposed therebetween. After alignment and placement, semiconductor device dies 320a, 320b, 320c and semiconductor wafer 350 may be bonded to one another. For example, semiconductor device dies 320a, 320b, 320c maybe hybrid bonded to semiconductor wafer 350, wherein front side metal features of semiconductor device dies 320a, 320b, 320c are bonded to front side metal features of semiconductor wafer 350, and front side dielectric material of semiconductor device dies 320a, 320b, 320c are bonded to front side dielectric material of semiconductor wafer 350, with the application of heat and pressure.

In yet another chip-to-wafer embodiment, as representatively illustrated in FIG. 3D′, semiconductor device dies 320a, 320b, 320c may be hybrid bonded to semiconductor wafer 350 with aqueous solution 300d disposed on a front side surface region of semiconductor device dies 320a, 320b, 320c, and aqueous solution 300d′ disposed on front side surface regions of semiconductor wafer 350. Aqueous solution 300d may be disposed on front side surfaces of semiconductor device dies 320a, 320b, 320c by operation of die pick-and-place tool 310 dipping semiconductor device dies 320a, 320b, 320c in a dip tank. Thereafter, die pick-and-place tool 310 aligns and lands semiconductor device dies (e.g., 320a) over semiconductor wafer 350 with aqueous solutions 300d, 300d′ disposed therebetween. After alignment and placement, semiconductor device dies 320a, 320b, 320c and semiconductor wafer 350 may be bonded to one another. For example, semiconductor device dies 320a, 320b, 320c maybe hybrid bonded to semiconductor wafer 350, wherein front side metal features of semiconductor device dies 320a, 320b, 320c are bonded to front side metal features of semiconductor wafer 350, and front side dielectric material of semiconductor device dies 320a, 320b, 320c are bonded to front side dielectric material of semiconductor wafer 350, with the application of heat and pressure.

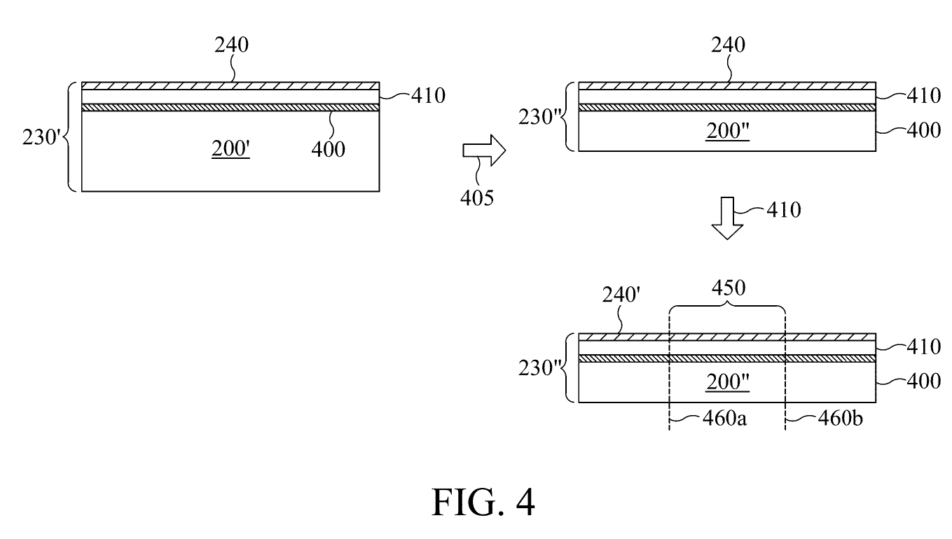

FIGS. 4 and 5 representatively illustrate cross-section views of intermediate stages in the formation of an immersion bonded semiconductor device in accordance with some embodiments. As used herein, the terms “submersion bond” or “immersion bond” (and contextual variants thereof), generally refer to a bond (e.g., a hybrid bond) formed between a first semiconductor device region (e.g., of a die) and a second semiconductor device region (e.g., of a wafer) with aqueous solution (e.g., hydroxide-rich alkaline solution) interposing, or otherwise disposed between, the first and second semiconductor device regions prior to or concurrent with formation of the bond.

As shown in FIG. 4, a top die wafer 230′ may comprise a substrate 200′, one or more front-end-of-line (FEOL) (e.g., device) layers 400, one or more back-end-of-line (BEOL) layers 410, and front side layer 240′. Front side layer 240′ comprises metal features and dielectric features. A back side planarization process 405 may be performed to remove substrate 200′ material from top die wafer 230′ to produced thinned substrate 200″. Back side planarization process 405 may comprise, e.g., a chemical mechanical polish (CMP). The CMP process may utilize etchants and abrasive, which may be applied to a back side surface of substrate 200′. Material of the back side surface of substrate 200′ is ground with a platen to planarize and remove back side material of substrate 200′. It will be appreciated by persons skilled in the art that the CMP process described herein is intended to be illustrative, and is not intended to limit the embodiments. Rather, any suitable planarization process, such as a physical grinding process or a series of one or more etches, may be alternatively or conjunctively utilized.

In a representative embodiment, substrate 200′ material layer may have a thickness of about 100 μm prior to planarized removal of material, and thinned substrate 200″ may have a thickness of about 5 μm after planarized removal of material. Thereafter, thinned top die wafer 230″ may be singulated along scribe lines 460a, 460b to produce top die 450. Singulation may be performed using a saw blade to slice through thinned top die wafer 230″ along scribe lines 460a, 460b. Persons skilled in the art will appreciate that utilizing a saw blade to singulate thinned top die wafer 230″ is merely one illustrative embodiment, and is not intended to be limiting. Alternative methods for singulating thinned top die wafer 230″, such as one or more etches, laser cutting, or the like may be alternatively or conjunctively utilized.

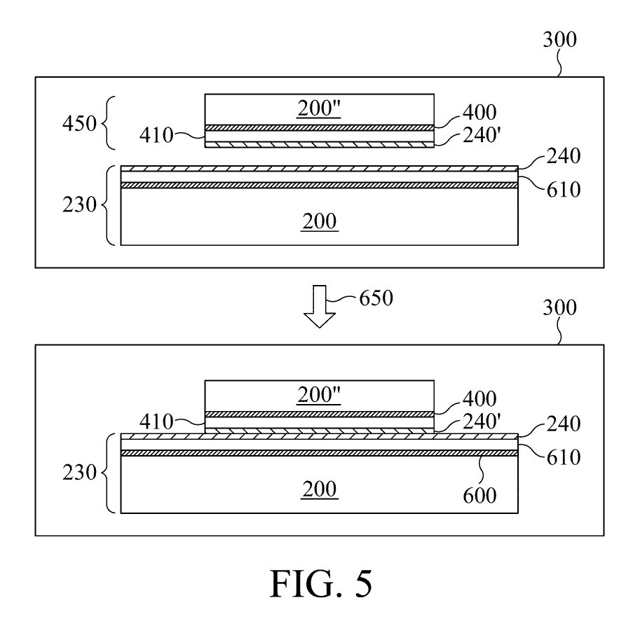

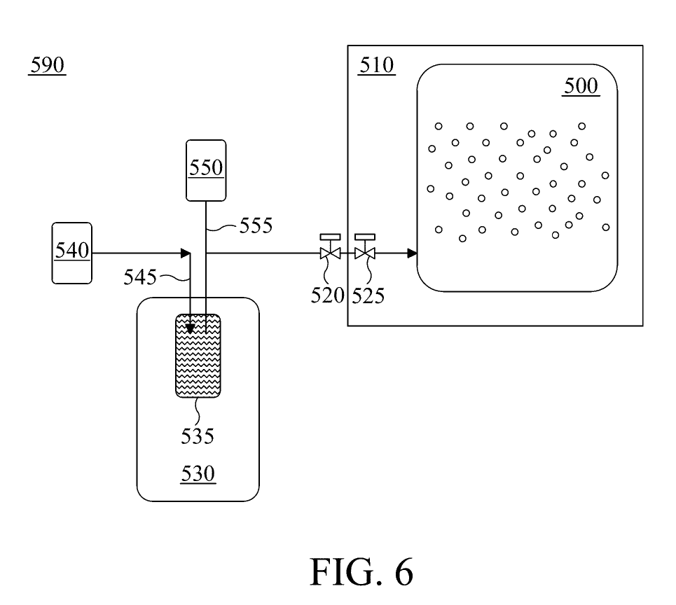

In accordance with an embodiment, aqueous solution may be disposed on a bottom die using a system 590 as representatively illustrated, for example, in FIG. 6. System 590 comprises bubbling cell 530 connected to vapor cell 510. Bubbling cell 530 comprises bubbling chamber 535 having a input line 545 for receiving a carrier gas (e.g., nitrogen). First pressure sensor 540 measures the flow of carrier gas into aqueous solution disposed in bubbling chamber 535. As carrier gas flows into bubbling chamber 535 and bubbles through aqueous solution, aqueous solution vapor borne up in the carrier gas flows through output line 555. Second pressure sensor 550 measures the pressure of aqueous solution vapor and carrier gas provided to vapor cell 510. Vapor cell 510 comprises vapor chamber 500 where aqueous solution vapor is delivered for submersion/immersion bonding of mated semiconductor device dies. Valves 520, 525 may provide for control of the flow of aqueous solution vapor and carrier gas to/from vapor chamber 500. Persons skilled in the art will appreciate that lines 545, 555 may include filters, traps, valves, or may otherwise be variously modified without departing from the scope of the embodiments disclosed herein.

In accordance with a representative aspect utilizing nitrogen as a carrier gas, the quantity of aqueous solution vapor delivered to vapor chamber 500 may be controlled with the following relationship of partial volumes and partial pressures:

$$\frac{{V}_{v}}{{V}_{n}} = \frac{{P}_{v}}{{P}_{n}}$$

where Vᵥ is the partial volume of aqueous solution vapor, Vₙ is the partial volume of nitrogen, Pᵥ is the partial pressure of aqueous solution vapor, and Pₙ is the partial pressure of nitrogen. The total pressure \hat{P} measured at second pressure sensor 550 is given as the sum of the partial pressures of nitrogen and aqueous solution vapor:

\hat{P}=Pₙ+Pᵥ.

Substituting for the partial pressure of nitrogen provides:

$$\frac{{V}_{v}}{{V}_{n}} = \frac{{P}_{v}}{\hat{P} - {P}_{v}} .$$

An alternative expression with terms collected in the partial pressure of aqueous solution vapor yields:

$$\hat{P} = {P}_{v} ( \frac{{V}_{n}}{{V}_{v}} + 1 ) .$$

In a representative embodiment, with reference to FIG. 5, bottom die region of wafer 230 is placed in vapor chamber 500 for immersion in alkaline aqueous solution vapor 300. Bottom die region of wafer 230 comprises substrate 200, one or more FEOL (e.g., device) layers 600, one or more BEOL layers 610, and front side layer 240. Front side layer 240 comprises metal features and dielectric features, as previously described. Alkaline aqueous solution vapor 300 immerses front side layer 240 of bottom die region of wafer 230 and front side layer 240′ of top die 450.

While immersed, top die 450 is brought into alignment and registered with bottom die region of wafer 230 and pre-bonded 650. The composite structure may thereafter be subjected to heat and pressure to hybrid bond top die 450 and bottom die region of wafer 230. The composite structure may be subjected to thermal annealing to improve the integrity of the bond. For example, pre-bonded top die 450 and bottom die region of wafer 230 may be annealed at a temperature between about 300° C. and about 400° C. Annealing may be performed for a period of time between, e.g., about 1 hour and about 2 hours. As temperature increases, hydroxide bonds (if any) in bond surface dielectric layers break and reform stronger Si—O—Si bonds. Accordingly, top die 450 and bottom die region of wafer 230 are bonded to one another through fusion bonds (and through Van Der Waals forces). During anneal, metal (e.g., copper) in bond pads diffuse into one another, so that metal-to-metal bonds are formed. In various embodiments, the resulting metal-to-metal and dielectric-to-dielectric bonds between top die 450 and bottom die region of wafer 230 are termed “hybrid bonds,” which are different from discrete metal-to-metal bonds or discrete Si—O—Si bonds. After hybrid bonding, the bonded structures may be sawed into a plurality of device packages. The singulated packages comprise stacked semiconductor packages.

In the bonding process, as temperature increases, the metal bond pads expand. The coefficient of thermal expansion (CTE) of the metal bond pads is higher than that of bonded dielectric material. Consequently, a mechanical stress may be applied that operates to pull dielectric material layers apart from one other. After the elevated temperature of the bonding process, the bonded composite structures are cooled. During the cooling stage, the metal bond pads contract, causing mechanical stresses to be produced. These stresses may cause delamination of the metal bond pads and dielectric layers. In a representative aspect, aqueous solution disposed between front side surfaces of top die 450 and bottom die region of wafer 230 operates to minimize stress attendant (or subsequent) to formation of hybrid bonds. Accordingly, delamination of metal pads and dielectric layers is reduced.

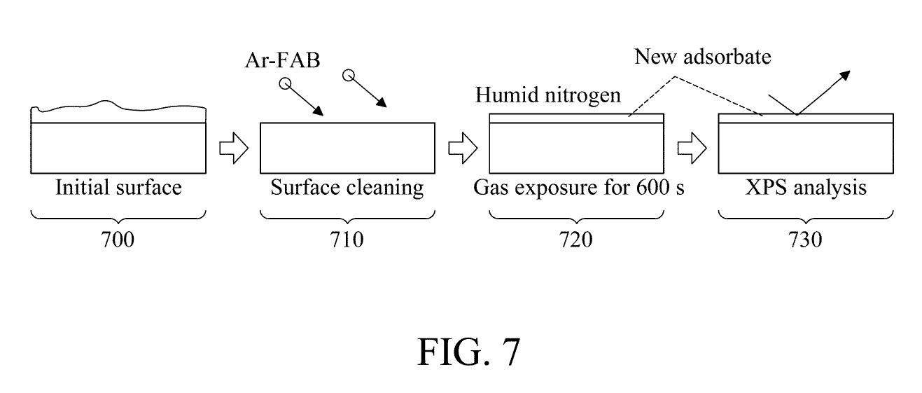

As generally illustrated in FIG. 7, a representative method for x-ray photoelectron spectroscopy (XPS) analysis of a semiconductor device surface adapted for immersion bonding includes a step 700 of providing a semiconductor device region surface, and a step 710 for cleaning the semiconductor device region surface with argon fast ion bombardment (Ar-FAB). In step 720, the cleaned semiconductor device surface is contacted with aqueous solution vapor in nitrogen gas for a time period of about 600 seconds. In step 730, XPS analysis is performed to characterize the semiconductor device region surface.

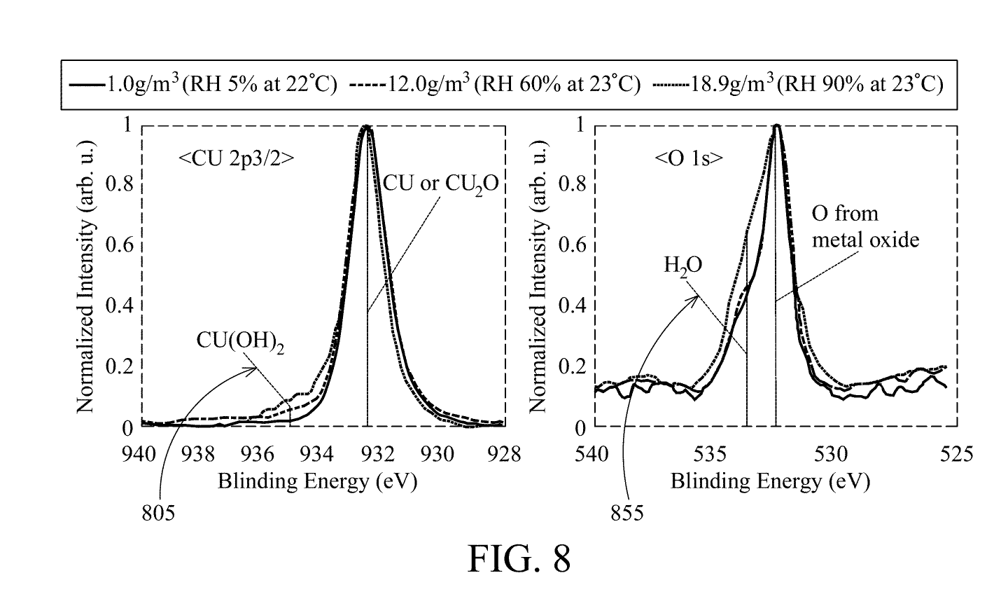

FIG. 8 representatively illustrates XPS data for a semiconductor device surface prepared in accordance with the method generally illustrated in FIG. 7. The XPS spectrum for copper (Cu) appears on the left, and shows the presence of copper hydroxide 805. The XPS spectrum for oxygen (0) appears on the right, and shows the presence of water 855. The combined results of Cu-XPS and O-XPS confirm the presence of copper hydroxide hydrate on the prepared semiconductor device surface. Other metals may be selected to produce various other metal hydroxide hydrates at a bonding surface of a semiconductor device surface attendant to forming a submersion/immersion bond, in accordance with various other representative embodiments.

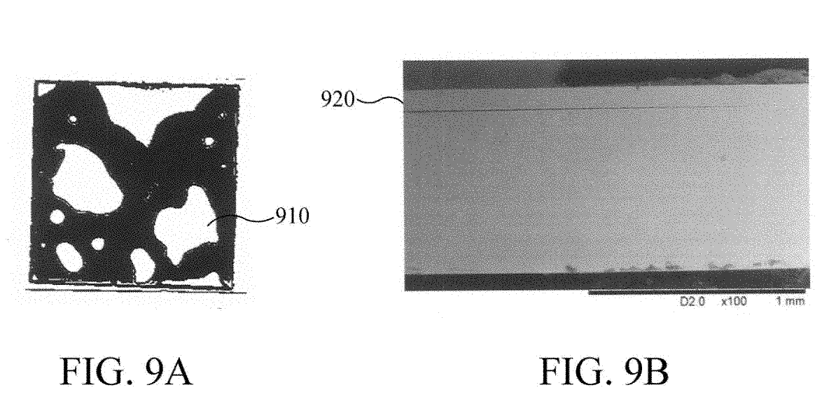

FIG. 9A representatively depicts confocal scanning acoustic microscopy (CSAM) analysis of a conventional bond formed in ambient atmosphere between a first semiconductor device and a second semiconductor device. As illustrated (in the plane of the bond), substantial defects (e.g., delamination region 910) are present at the bond interface. FIG. 9B representatively depicts tunnelling electron microscopy (TEM) analysis of an elevation cross-section of the conventional bond shown in FIG. 9A. Crack region 920 corresponds to delamination at the interface of the conventional bond.

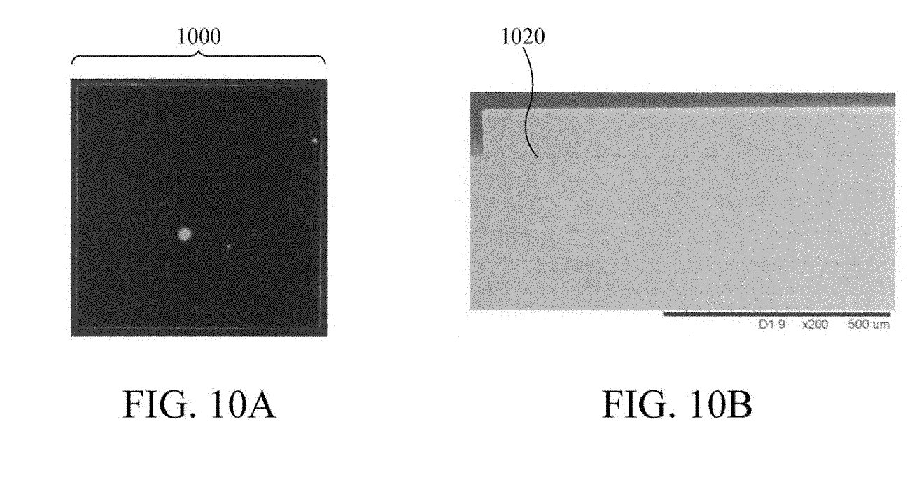

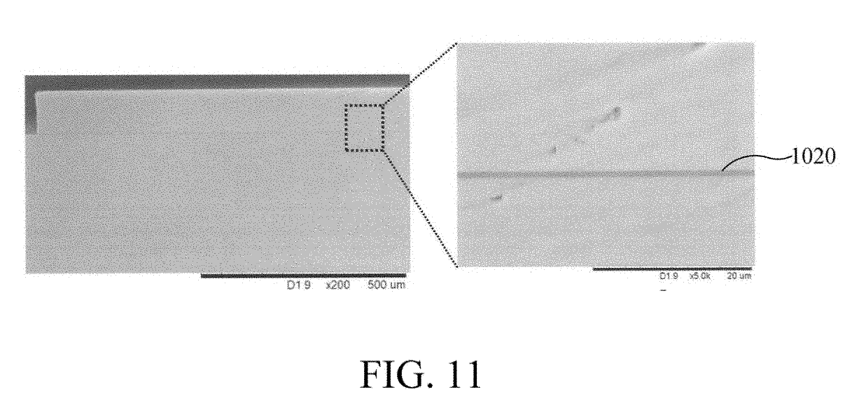

FIG. 10A representatively depicts CSAM analysis of an immersion hybrid bond formed between a first semiconductor device and a second semiconductor device, in accordance with a representative embodiment. As illustrated (in the plane of the immersion hybrid bond), the field of the bond is substantially uniform without significant defect (e.g., delamination) at the immersion hybrid bond interface. FIG. 10B representatively depicts TEM analysis of an elevation cross-section of the immersion hybrid bond shown in FIG. 10A. Adhesion region 1020 maintains improved integrity without significant cracking or delamination at the interface of the immersion hybrid bond. FIG. 11 representatively illustrates an enlarged view of the TEM analysis of FIG. 10B.

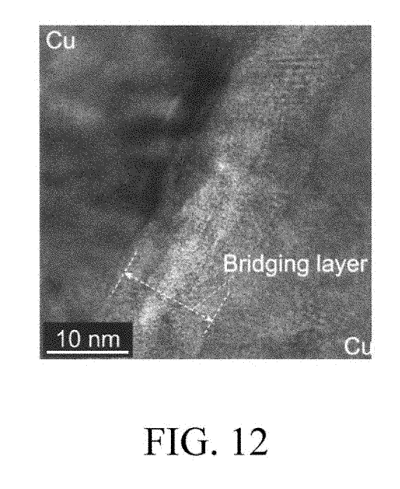

FIG. 12 represenatively illustrates TEM analysis of a cross-section of a bridging layer in an immersion bond formed between a metal feature of a first semiconductor device and a metal feature of a second semiconductor device, in accordance with an embodiment. The bonding layer interface comprises an amorphous layer about 15 nm thick. The bridging layer demonstrates no readily visible voids throughout the interface.

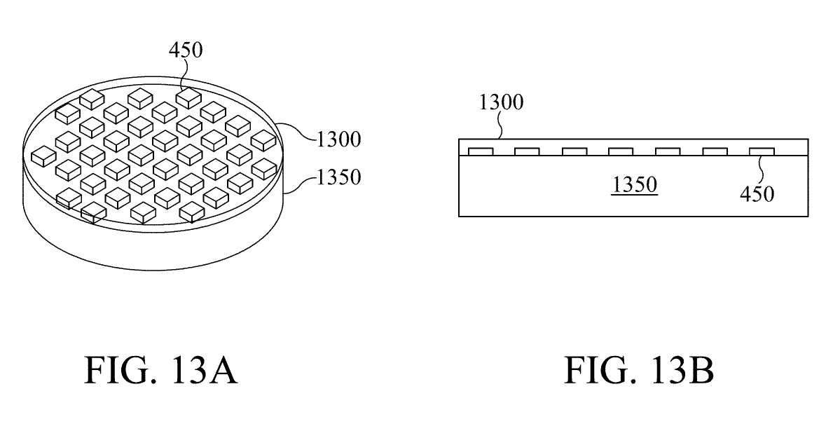

FIGS. 13A-17A (perspective views) and 13B-17B (corresponding cross-section views) illustrate various manufacturing stages that may be engaged after forming an immersion bond between a plurality of semiconductor dies (e.g., top die 450 comprising a representative one of the plurality of semiconductor dies) and a bottom device wafer 1350. In the chip-on-wafer (CoW) embodiment representatively illustrated in FIGS. 13A and 13B, top dies are immersion bonded to corresponding device die regions of bottom device wafer 1350. Thereafter, dielectric layer 1300 is deposited over bottom device wafer 1350 and on exposed surfaces of top dies (e.g., top die 450). In an embodiment, dielectric layer 1300 may comprise a polymer, which may be a photo-sensitive material such as polybenzoxazole (PB0), polyimide, benzocyclobutene (BCB), or the like, that may be patterned using a lithography mask. In other embodiments, dielectric layer 1300 may be formed of a nitride (e.g., silicon nitride), an oxide (e.g., silicon oxide), a glass (e.g., pohosphosilicate glass (PSG), borosilicate glass (BSG), boron-doped phosphosilicate glass (BPSG)), or the like. Dielectric layer 1300 may be formed by spin coating, lamination, CVD, or the like, or a combination thereof. In a representative embodiment, dielectric layer 1300 may be planarized (e.g., with CMP processing) to produce an ultrathin top die thickness of about 5 μm.

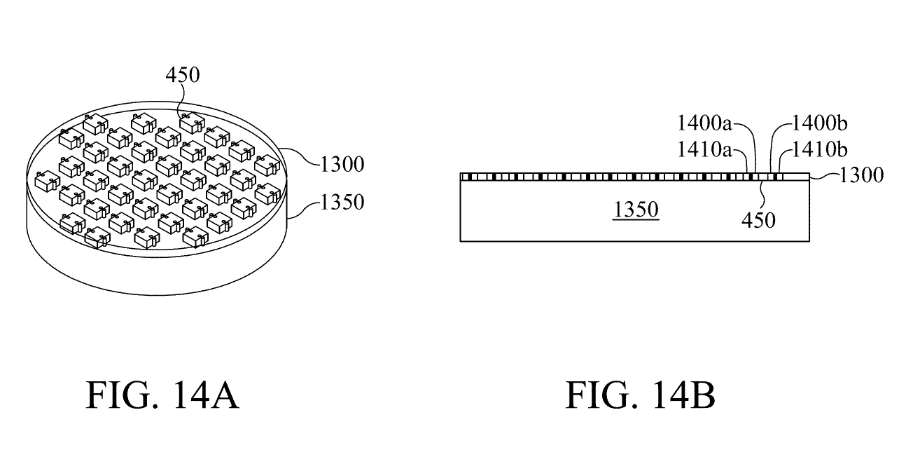

As representatively illustrated in FIGS. 14A and 14B, dielectric layer 1300 may be patterned to form openings to expose portions of electrical connectors and die connectors. Patterning may be accomplished by any suitable process, such as by employing lithographic exposure of a photo-sensitive material, followed by development and etching (e.g., one or more anisotropic etch processes). If dielectric layer 1300 is a photo-sensitive material, dielectric layer 1300 can be developed after exposure. Through-silicon vias (TSVs) 1400a, 1400b may be formed in top dies (e.g.,top die 450), and through-molding vias (TMVs) 1410a, 1410b may be formed in dielectric layer 1300. A conductive material may be formed in the openings. The conductive material may be formed by plating, such as electroplating or electroless plating, or the like. The conductive material may comprise a metal (e.g., copper, titanium, tungsten, aluminum, or the like).

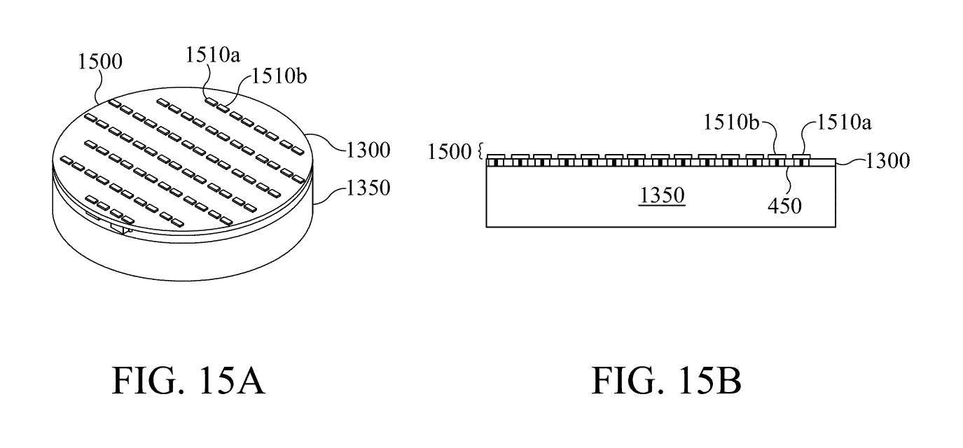

As representatively illustrated in FIGS. 15A and 15B, application of various known photolithography, etching, and deposition processes may be used to form an redistribution layer (RDL) 1500 over TSVs 1400a, 1400b and TMVs 1410a, 1410b. RDL 1500 may comprise first metallization feature 1510a electrically coupling first TMV 1410a to first TSV 1400a, and second metallization feature 1510b electrically coupling second TMV 1410b to second TSV 1400b. In accordance with a representative embodiment, a seed layer (not shown) may be formed on or in a dielectric layer (not shown) of RDL 1500. In some embodiments, the seed layer may comprise a metal layer, which may be a single layer or a composite layer comprising a plurality of sub-layers formed of different materials. In some embodiments, the seed layer comprises a titanium layer and a copper layer over the titanium layer. The seed layer may be formed using, e.g., physical vapor deposition (PVD), or the like. Photoresist is then formed and patterned on the seed layer. The photoresist may be formed by spin coating, or the like, and may be exposed to light for patterning. The pattern of the photoresist corresponds to a metallization pattern. The patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, e.g., copper, titanium, tungsten, aluminum, or the like, or a combination thereof. Thereafter, photoresist and portions of the seed layer on which conductive material is not formed are removed. The photoresist may be removed by an acceptable ashing or stripping process, e.g., using an oxygen plasma, or the like. Once the photoresist is removed, exposed portions of the seed layer are removed using an acceptable etching process, e.g., wet or dry etching. In accordance with a representative embodiment, remaining portions of the seed layer and conductive material form a metallization pattern of a redistribution structure. Alternatively, plural dielectric layers and metallization layers may be similarly formed over a dielectric layer to produce a redistribution structure that includes one or more dielectric layers and one or more metallization layers. In accordance with various representative embodiments, a redistribution structure may include any number of dielectric layers, metallization patterns, and/or vias. For example, vias may be formed during the formation of a metallization pattern by forming a seed layer and conductive material of the metallization pattern in an opening of an underlying dielectric layer. The vias may therefore interconnect and electrically couple various metallization layers in a redistribution structure. In accordance with a representative embodiment, RDL 1500 may comprise a fan-out (FO) structure.

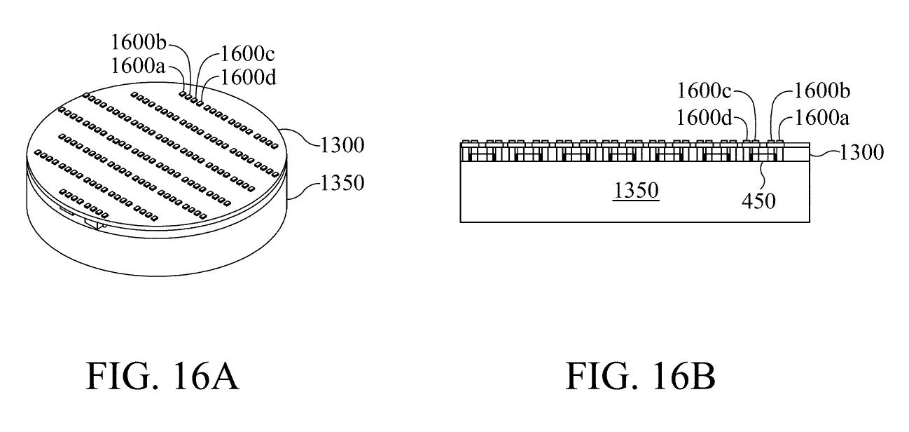

As representatively illustrated in FIGS. 16A and 16B, application of various known photolithography, etching, and deposition processes may be used to form an under bump metallurgy (UBM) layer over RDL 1500 metallization features 1510a, 1510b. The UBM layer may comprise first UBM pad 1600a and second UBM pad 1600b electrically coupled to first metallization feature 1510a, and third UBM pad 1600c and fourth UBM pad 1600d electrically coupled to second metallization feature 1510b. UBM pads 1600a, 1600b, 1600c, 1600d may be formed in etched openings (not shown) of a dielectric material (not shown). For example, a seed layer (not shown) may be formed in the etched openings. In some embodiments, the seed layer may comprise a metal layer, which may be a single layer or a composite layer having a plurality of sub-layers formed of different materials. In some embodiments, the seed layer comprises a titanium layer and a copper layer over the titanium layer. The seed layer may be formed using, for example, PVD, or the like. Photoresist may then be formed and patterned on the seed layer. The photoresist may be formed by spin coating, or the like, and may be exposed to light for patterning. The pattern of the photoresist corresponds to subsequently formed UBM pads 1600a, 1600b, 1600c, 1600d. Patterning forms openings through the photoresist to expose the seed layer. A conductive material is formed in the openings of the photoresist and on the exposed portions of the seed layer. The conductive material may be formed by plating, such as electroplating or electroless plating, or the like. The conductive material may comprise a metal, e.g., copper, titanium, tungsten, aluminum, or the like. Thereafter, photoresist and portions of the seed layer on which conductive material is not formed are removed. The photoresist may be removed by a suitable ashing or stripping process, e.g., using an oxygen plasma, or the like. Once the photoresist is removed, exposed portions of the seed layer may be removed, such as by using an acceptable etching process, e.g., wet or dry etching. Remaining portions of the seed layer and conductive material form UBM pads 1600a, 1600b, 1600c, 1600d.

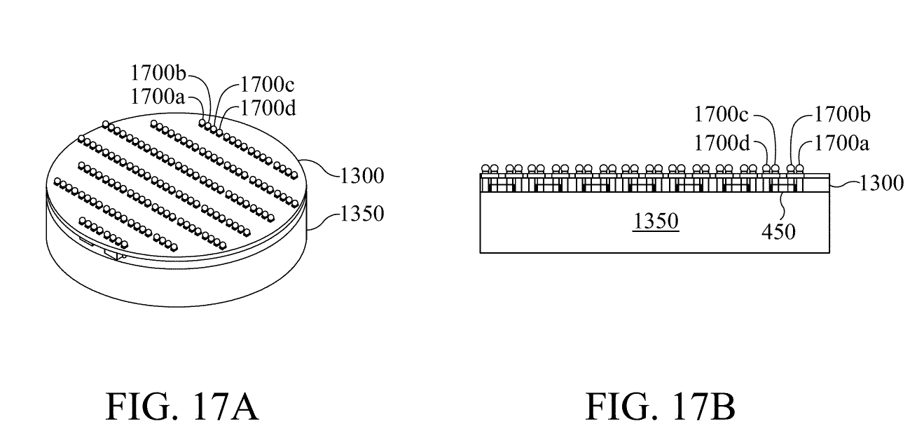

As representatively illustrated in FIGS. 17A and 17B, conductive connectors 1700a, 1700b, 1700c, 1700d (e.g., solder bumps) may be formed over and on UBM pads 1600a, 1600b, 1600c, 1600d, respectively. Conductive connectors 1700a, 1700b, 1700c, 1700c may comprise ball grid array (BGA) connectors, solder balls, metal pillars, controlled collapse chip connection (C4) bumps, micro bumps (μbumps), electroless nickel-electroless palladium-immersion gold (ENEPIG) technique formed bumps, or the like. Conductive connectors 1700a, 1700b, 1700c, 1700d may include a conductive material such as solder, copper, aluminum, gold, nickel, silver, palladium, tin, or the like, or a combination thereof. In some embodiments, conductive connectors 1700a, 1700b, 1700c, 1700d may be formed by initially depositing a layer of solder with commonly used methods, e.g., evaporation, electroplating, printing, solder transfer, ball placement, or the like. Once a layer of solder has been formed on the structure, a reflow may be performed in order to shape the material into the desired bump shapes. In another embodiment, conductive connectors 1700a, 1700b, 1700c, 1700d may comprise metal pillars (e.g., copper pillars) formed by sputtering, printing, electroplating, electroless plating, CVD, or the like. The metal pillars may be substantially solder-free and have substantially vertical sidewalls. In some embodiments, a metal cap layer may be formed on the top of the metal pillar connectors. The metal cap layer may include nickel, tin, tin-lead, gold, silver, palladium, indium, nickel-palladium-gold, nickel-gold, or the like, or a combination thereof, and may be formed by a plating process. In accordance with a representative embodiment, conductive connectors 1700a, 1700b, 1700c, 1700d may comprise solder balls having a diameter ranging from, e.g., about 150 μm to about 300 μm.

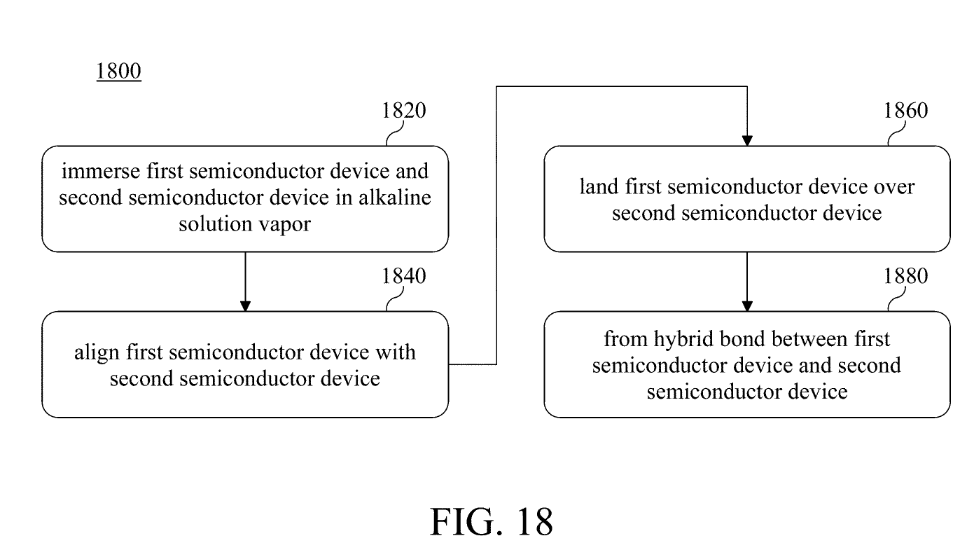

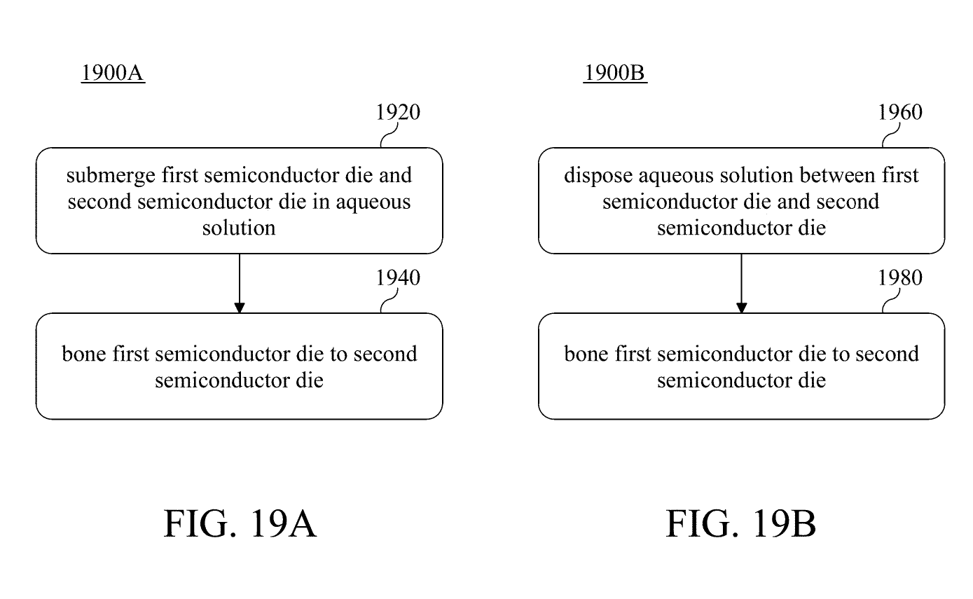

FIGS. 18, 19A, and 19B representatively illustrate methods for manufacturing an immersion/submersion bonded semiconductor device in accordance with various embodiments. In step 1820 of a representative method 1800, a first semiconductor device and second semiconductor device are immersed in an alkaline aqueous solution vapor. In step 1840, the first semiconductor device is aligned with the second semiconductor device. In step 1860, the first semiconductor device is landed over the second semiconductor device. In step 1880, a hybrid bond is formed between the first semiconductor device and the second semiconductor device.

In step 1920 of another representative method 1900A, a first semiconductor die and a second semiconductor die are submerged in an aqueous solution. In step 1940, the first semiconductor die is bonded to the second semiconductor die.

In step 1960 of yet another representative method 1900B, aqueous solution is disposed between a first semiconductor die and a second semiconductor die. In step 1980 the first semiconductor die is bonded to the second semiconductor die.

In accordance with an embodiment, a method of manufacturing a semiconductor device includes submerging a first semiconductor die and a second semiconductor die in an aqueous solution, and while submerged, bonding the first semiconductor die to the second semiconductor die. The aqueous solution may comprise deionized water. The aqueous solution may have a pH of about 7.0. The aqueous solution may have a pH greater than 7.0. The aqueous solution may comprise hydroxide ion. A first wafer may comprise the first semiconductor die, where immersing the first semiconductor die includes immersing the first wafer in the aqueous solution, and bonding the first semiconductor die includes bonding the first wafer to the second semiconductor die. A second wafer may comprise the second semiconductor die, where immersing the second semiconductor die includes immersing the second wafer in the aqueous solution, and bonding the first semiconductor die to the second semiconductor die includes bonding the first wafer to the second wafer. The first semiconductor die and the second semiconductor die may be immersed in one of a liquid phase or a vapor phase of the aqueous solution. Bonding the first semiconductor die to the second semiconductor die may comprise forming a hybrid bond between corresponding dielectric regions of the first semiconductor die and the second semiconductor die, and between corresponding metal regions of the first semiconductor die and the second semiconductor die.

In accordance with another embodiment, a method of manufacturing a semiconductor device includes disposing an aqueous solution between a first semiconductor die and a second semiconductor die, and after disposing the aqueous solution between the first semiconductor die and the second semiconductor die, bonding the first semiconductor die to the second semiconductor die. The aqueous solution may comprise deionized water. The aqueous solution may a pH of about 7.0. The aqueous solution may have a pH greater than 7.0. The aqueous solution may comprise hydroxide ion. The method may further include dipping the second semiconductor die in a dip tank to dispose the aqueous solution on the second semiconductor die. The method may further include after dipping, aligning the second semiconductor die with the first semiconductor die. The method may further include after aligning, landing the second semiconductor die on the first semiconductor die. A first wafer may comprise the first semiconductor die, where the first semiconductor die is disposed in a first region of the first wafer, the aqueous solution is disposed over the first region, the second semiconductor die is disposed over the aqueous solution, and bonding the first semiconductor die to the second semiconductor die may include bonding the first wafer to the second semiconductor die. A second wafer may comprise the second semiconductor die, where the second semiconductor die is disposed in a second region of the second wafer, the aqueous solution is disposed over the second region, and bonding the first semiconductor die to the second semiconductor die may include bonding the first wafer to the second wafer. The aqueous solution may be in one of a liquid phase or a vapor phase. Bonding the first semiconductor die to the second semiconductor die may comprise forming a hybrid bond between corresponding dielectric regions of the first semiconductor die and the second semiconductor die, and between corresponding metal regions of the first semiconductor die and the second semiconductor die.

In accordance with yet another embodiment, a method of manufacturing a semiconductor device includes immersing a first semiconductor device and a second semiconductor device in an alkaline solution vapor, aligning the first semiconductor device with the second semiconductor device, (while immersed) landing the first semiconductor device over the second semiconductor device, and (after landing and while immersed) hybrid bonding a first dielectric region of the first semiconductor device to a second dielectric region of the second semiconductor device, and a first metal region of the first semiconductor device to a second metal region of the second semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
submerge a first semiconductor die and a second semiconductor die in an aqueous solution; and
while submerged, bonding the first semiconductor die to the second semiconductor die.

2. The method of claim 1, wherein the aqueous solution comprises deionized water.

3. The method of claim 2, wherein the aqueous solution has a pH of about 7.0.

4. The method of claim 2, wherein the aqueous solution has a pH greater than 7.0.

5. The method of claim 4, wherein the aqueous solution comprises hydroxide ion.

6. The method of claim 1, wherein:
a first wafer comprises the first semiconductor die;
immersing the first semiconductor die comprises immersing the first wafer in the aqueous solution; and
bonding the first semiconductor die comprises bonding the first wafer to the second semiconductor die.

7. The method of claim 6, wherein:
a second wafer comprises the second semiconductor die;
immersing the second semiconductor die comprises immersing the second wafer in the aqueous solution; and
bonding the first semiconductor die to the second semiconductor die comprises bonding the first wafer to the second wafer.

8. The method of claim 1, wherein the first semiconductor die and the second semiconductor die are immersed in one of a liquid phase or a vapor phase of the aqueous solution.

9. The method of claim 1, wherein bonding the first semiconductor die to the second semiconductor die comprises forming a hybrid bond between corresponding dielectric regions of the first semiconductor die and the second semiconductor die, and between corresponding metal regions of the first semiconductor die and the second semiconductor die.

10. A method of manufacturing a stacked semiconductor device, the method comprising:
disposing an aqueous solution between a first semiconductor device and a second semiconductor device; and
after disposing the aqueous solution between the first semiconductor device and the second semiconductor device, bonding the first semiconductor device to the second semiconductor device.

11. The method of claim 10, wherein the aqueous solution comprises deionized water.

12. The method of claim 11, wherein the aqueous solution has a pH of about 7.0.

13. The method of claim 11, wherein the aqueous solution has a pH greater than 7.0.

14. The method of claim 13, wherein the aqueous solution comprises hydroxide ion.

15. The method of claim 14, further comprising:
dipping the second semiconductor device in a dip tank to dispose the aqueous solution on the second semiconductor device;
after dipping, aligning the second semiconductor device with the first semiconductor device; and
after aligning, landing the second semiconductor device on the first semiconductor device.

16. The method of claim 14, wherein:
a first wafer comprises the first semiconductor device;
the first semiconductor device is disposed in a first region of the first wafer;
the aqueous solution is disposed over the first region;
the second semiconductor device is disposed over the aqueous solution; and
bonding the first semiconductor device to the second semiconductor device comprises bonding the first wafer to the second semiconductor device.

17. The method of claim 16, wherein:
a second wafer comprises the second semiconductor device;
the second semiconductor device is disposed in a second region of the second wafer;
the aqueous solution is disposed over the second region; and
bonding the first semiconductor device to the second semiconductor device comprises bonding the first wafer to the second wafer.

18. The method of claim 14, wherein the aqueous solution is in one of a liquid phase or a vapor phase.

19. The method of claim 14, wherein bonding the first semiconductor device to the second semiconductor device comprises forming a hybrid bond between corresponding dielectric regions of the first semiconductor device and the second semiconductor device, and between corresponding metal regions of the first semiconductor device and the second semiconductor device.

20. A method of manufacturing a hybrid bonded semiconductor device, the method comprising:
immersing a first semiconductor device and a second semiconductor device in a alkaline solution vapor;
aligning the first semiconductor device with the second semiconductor device;
while immersed, landing the first semiconductor device over the second semiconductor device; and
after landing and while immersed, hybrid bonding a first dielectric region of the first semiconductor device to a second dielectric region of the second semiconductor device, and a first metal region of the first semiconductor device to a second metal region of the second semiconductor device.
